(19) United States
(12) Patent Application Publication
(10) Pub. No.: US 2025/0379180 A1
(43) Pub. Date: Dec. 11, 2025

(54) SEMICONDUCTOR PACKAGE

(71) Applicant: Samsung Electronics Co., Ltd., Suwon-si (KR)

(72) Inventors: Wonil SEO, Suwon-si (KR); Jiwon SHIN, Suwon-si (KR); Kundae YEOM, Suwon-si (KR)

(73) Assignee: Samsung Electronics Co., Ltd., Suwon-si (KR)

(21) Appl. No.: 18/976,449

(22) Filed: Dec. 11, 2024

(30) Foreign Application Priority Data
Jun. 10, 2024 (KR) 10-2024-0074813

(51) Int. Cl. H01L 23/00; H01L 23/31; H01L 23/498; H01L 25/065; H10B 80/00

(52) U.S. Cl. CPC H01L 24/50; H01L 23/3135; H01L 23/49816; H01L 23/49838; H01L 24/08; H01L 24/32; H01L 24/73; H01L 25/0657; H01L 2224/50; H01L 2224/73269; H01L 2225/06506; H01L 2225/0651; H01L 2225/06562; H10B 80/00

(57) ABSTRACT

A semiconductor package includes a substrate including bonding pads, semiconductor chips stacked on the substrate and each including a lower surface and an upper surface, and connection pads on the upper surface, connection films spaced apart from each other in a first direction, the connection films electrically connecting the connection pads and corresponding ones of the bonding pads to each other in a second direction intersecting the first direction, a mold covering the semiconductor chips and the connection films, and connection bumps being under the substrate, the connection bumps electrically connected to the bonding pads. Each of the connection films includes a flexible film covering at least two connection pads adjacent to each other in the first direction, among the connection pads, and conductive lines extending in the second direction on the flexible film, the conductive lines respectively connected to the at least two connection pads.

### CROSS-REFERENCE TO RELATED APPLICATION(S)

This application claims benefit of priority to Korean Patent Application No. 10-2024-0074813 filed on Jun. 10, 2024 in the Korean Intellectual Property Office, the disclosure of which is incorporated herein by reference in its entirety.

### BACKGROUND

The present disclosure relates to semiconductor packages.

With the development of the electronics industry, demand for implementation of higher performance and miniaturization of electronic components has been increasing. A semiconductor package including a plurality of wire-bonded semiconductor chips has limitations in implementing a finer pitch of a connection pad and reducing a thickness of a semiconductor package due to a shape of a bonding wire, for example, a ball size, a height of a wire loop, or the like.

### SUMMARY

Some example embodiments of the present inventive concepts provide semiconductor packages having improved productivity and/or reliability.

According to an example embodiment of the present inventive concepts, a semiconductor package includes a substrate including bonding pads, a plurality of semiconductor chips stacked on the substrate, the plurality of semiconductor chips each including a lower surface facing the substrate, an upper surface opposite to the lower surface, and connection pads being on the upper surface, a plurality of connection films spaced apart from each other in a first direction, the plurality of connection films electrically connecting the connection pads and corresponding one of the bonding pads to each other in a second direction, intersecting the first direction, a mold covering the plurality of semiconductor chips and the plurality of connection films, and connection bumps being under the substrate, the connection bumps electrically connected to the bonding pads. Each of the plurality of connection films may include a flexible film covering at least two connection pads adjacent to each other in the first direction, among the connection pads, and a plurality of conductive lines extending in the second direction on the flexible film, the plurality of conductive lines respectively connected to the at least two connection pads.

According to an example embodiment of the present inventive concepts, a semiconductor package includes a substrate including bonding pads, a plurality of semiconductor chips including at least one lower semiconductor chip and at least one upper semiconductor chip, the at least one lower semiconductor chip and the at least one upper semiconductor chip stacked in order on the substrate, the at least one lower semiconductor chip and the at least one upper semiconductor chip each including connection pads, a plurality of connection films electrically connecting the connection pads and the bonding pads to each other, the plurality of connection films each including a flexible film and a conductive pattern, the flexible film having a first surface facing the substrate and a second surface opposite to the first surface, the conductive pattern extending along at least one surface, among the first and second surfaces, and a mold between the plurality of semiconductor chips and the plurality of connection films. The plurality of connection films may include a first sub-film and a second sub-film, the first sub-film electrically connecting the connection pads of the at least one lower semiconductor chip and the bonding pads to each other, the second sub-film electrically connecting the connection pads of the at least one upper semiconductor chip and the bonding pads to each other.

According to an example embodiment of the present inventive concepts, a semiconductor package includes a substrate including bonding pads, a plurality of semiconductor chips stacked on the substrate, the plurality of semiconductor chips each including a lower surface facing the substrate, an upper surface opposite to the lower surface, and connection pads on the upper surface, a plurality of connection films electrically connecting the connection pads and the bonding pads to each other, a mold encapsulating the plurality of semiconductor chips and the plurality of connection films, the mold filling a space between the plurality of semiconductor chips and the plurality of connection films, and connection bumps being under the substrate, the connection bumps electrically connected to the bonding pads. The plurality of connection films may include a flexible film extending on the connection pads and the bonding pads, a plurality of conductive lines on the flexible film, the plurality of conductive lines electrically connecting the connection pads and the bonding pads corresponding to each other, and through-holes being between the plurality of conductive lines and passing through the flexible film.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1A is a perspective view of a semiconductor package according to an example embodiment, and FIG. 1B is an exploded view of FIG. 1A;

FIGS. 2A to 2D are diagrams of connection films according to some example modifications;

FIG. 3A is an exploded view of a semiconductor package according to an example embodiment, and FIG. 3B is a partially enlarged view of a connection member according to an example embodiment;

FIG. 4A is a perspective view of a semiconductor package according to an example embodiment, and FIG. 4B is a plan view of a connection film according to an example embodiment;

FIGS. 5 to 10 are diagrams of forms of a connection film applied to a semiconductor package according to an example modification; and

FIGS. 11A to 11D are diagrams of a process of manufacturing a semiconductor package according to an example embodiment.

### DETAILED DESCRIPTION

Hereinafter, some example embodiments will be described in detail. Unless otherwise described, the terms such as “upper,” “upper portion,” “upper surface,” “lower,” “lower portion,” “lower surface,” and “side surface” are based on the drawings, and may vary depending on a direction in which a component is actually arranged.

In addition, ordinal numbers such as “first,” “second,” “third,” and the like may be used as labels for specific elements, operations, directions, and the like, to distinguish various elements, steps, directions, and the like from one another. A term, not described in the specification using “first,” “second,” and the like, may still be referred to as “first” or “second” in the claims. In addition, a term referenced by a particular ordinal number (for example, “first” in a particular claim) may be described elsewhere with a different ordinal number (for example, “second” in the specification or another claim).

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

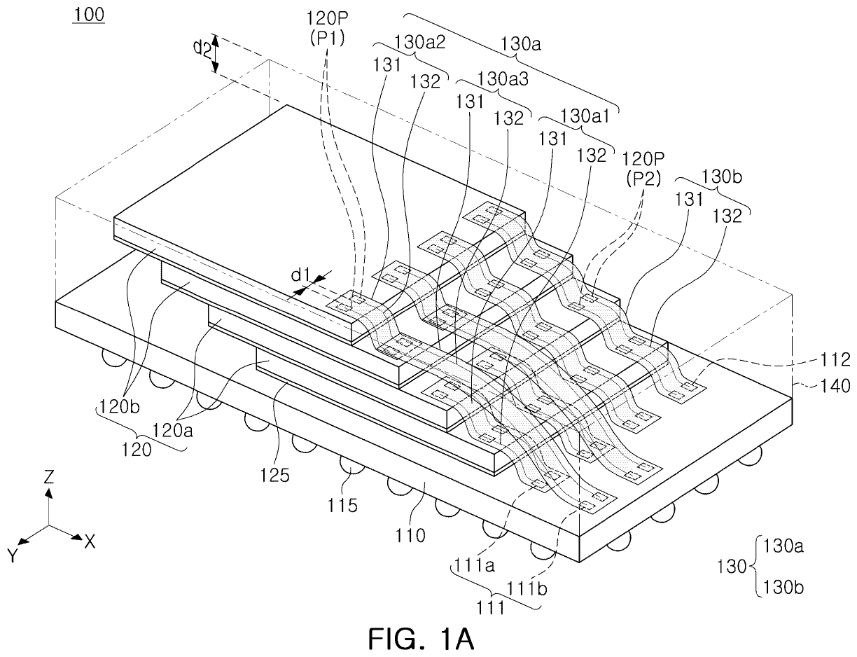

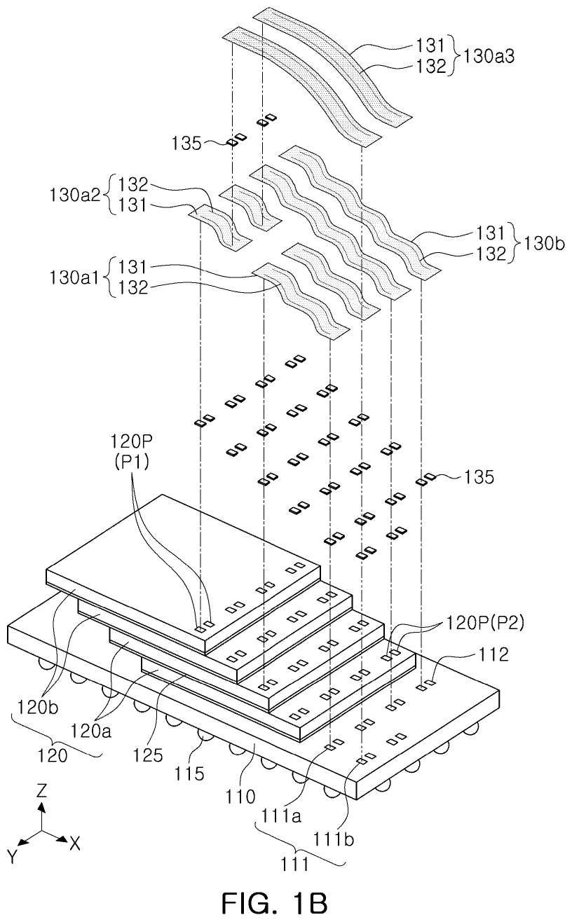

FIG. 1A is a perspective view of a semiconductor package 100 according to an example embodiment, and FIG. 1B is an exploded view of FIG. 1A.

Referring to FIGS. 1A and 1B, a semiconductor package 100 according to an example embodiment may include a substrate 110, a plurality of semiconductor chips 120, a plurality of connection films 130, and a mold 140. According to some example embodiments, the plurality of connection films 130 including conductive lines, formed in a thin film on a flexible film, may form an electrical connection path between the substrate 110 and the plurality of semiconductor chips 120 stacked thereon, thereby miniaturizing an electrical connection path and a connection pad without a structural restriction of a bonding wire, for example, a restriction of a ball size of a wire, a height of a wire loop, or the like, and reducing a thickness of a semiconductor package. In addition, a process of manufacturing a semiconductor package may be simplified by the plurality of connection films 130, and connection reliability of semiconductor chips may be further improved.

The substrate 110 may be a substrate for a semiconductor package including a printed circuit board (PCB), a ceramic substrate, a glass substrate, a tape interconnection substrate, or the like. For example, the substrate 110 may be a double-sided PCB or a multilayer PCB.

The substrate 110 may include bonding pads 111 and 112. The bonding pads 111 and 112 are disposed on an upper surface of the substrate 110, and may include at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn). The bonding pads 111 and 112 may include carbon (C). The bonding pads 111 and 112 may be electrically connected to connection bumps 115 disposed below the substrate 110. The connection bumps 115 may include, for example, tin (Sn) or an alloy including tin (Sn). The substrate 110 may include a lower pad on which the connection bumps 115 are disposed, and an internal circuit connecting the lower pad and the bonding pads 111 and 112 to each other. The connection bumps 115 may be electrically connected to an external device such as a module substrate, a system board, or the like.

The bonding pads 111 and 112 may include first bonding pads 111 and second bonding pads 112 spaced apart from each other. For example, the first bonding pads 111 may be signal pads connected to input and output terminals of a data signal, and the second bonding pads 112 may be power and ground pads connected to a power terminal and a ground terminal. The first bonding pads 111 may include a first group of bonding pads 111a and a second group of bonding pads 111b that are electrically insulated from each other, in view of a path of a signal.

The plurality of semiconductor chips 120 may be stacked on the substrate 110 in a vertical direction (Z-direction). The plurality of semiconductor chips 120 may be attached to the substrate 110 or may be attached to each other by an adhesive film 125. The adhesive film 125 may be formed using an adhesive film, an adhesive paste, or the like. The adhesive film 125 may be a die attach film (DAF), but the present inventive concepts are not limited thereto.

The plurality of semiconductor chips 120 may include connection pads 120P electrically connected to the plurality of connection films 130. The connection pads 120P may include one of copper (Cu), nickel (Ni), titanium (Ti), aluminum (Al), or alloys thereof. The connection pads 120P may include first connection pads P1 and second connection pads P2. The first connection pads P1 may include terminals for inputting and outputting a data signal, and the second connection pads P2 may include terminals for supplying power and ground voltages.

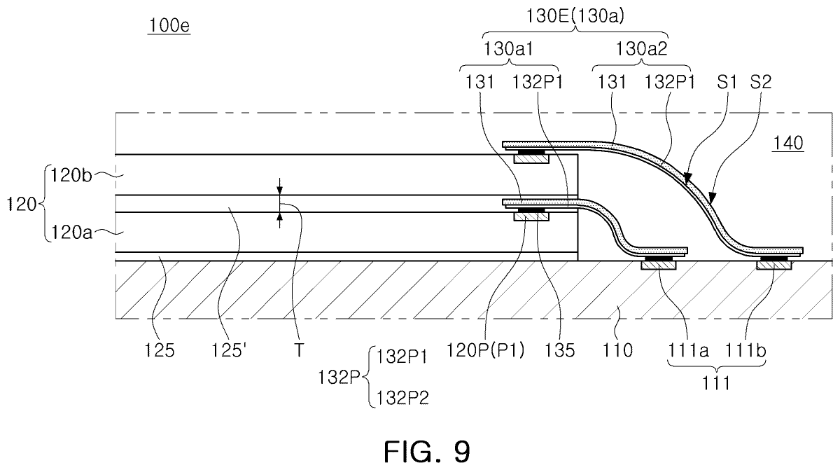

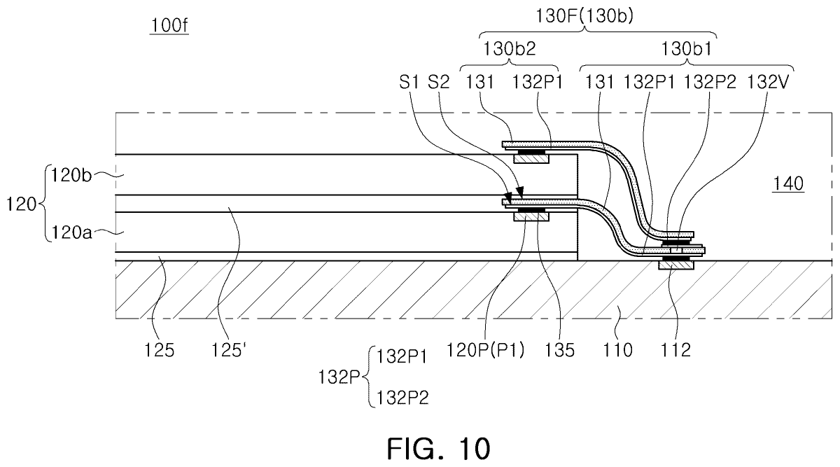

The plurality of semiconductor chips 120 may have a lower surface facing the substrate 110 and an upper surface on which the connection pads 120P are arranged. The adhesive film 125 may be disposed on a lower surface of each of the plurality of semiconductor chips 120. The plurality of semiconductor chips 120 may be offset in one direction (e.g., an X-direction) to expose the connection pads 120P in the vertical direction (Z-direction). In some example embodiments (e.g., FIGS. 9 and 10), the plurality of semiconductor chips 120 may be aligned in the vertical direction (Z-direction), such that the connection pads 120P may overlap each other.

The plurality of semiconductor chips 120 may include a non-volatile memory chip such as a flash memory, a phase-change random access memory (PRAM), a magnetoresistive random access memory (MRAM), a ferroelectric random access memory (FeRAM), or a resistive random access memory (RRAM), and/or a volatile memory chip such as a dynamic random access memory (DRAM) or a static random access memory (SRAM). The plurality of semiconductor chips 120 may include the same type of semiconductor chips, but the present inventive concepts are not limited thereto. Depending on example embodiments, the plurality of semiconductor chips 120 may include different types of semiconductor chips.

The plurality of semiconductor chips 120 may include a lower semiconductor chip 120a and an upper semiconductor chip 120b that are electrically insulated from each other in view of a signal path and form different channels from each other. For example, the plurality of semiconductor chips 120 may include at least two lower semiconductor chips 120a and at least two upper semiconductor chips 120b. The number of lower semiconductor chips 120a may be equal to the number of upper semiconductor chips 120b, but the present inventive concepts are not limited thereto. In some example embodiments (e.g., FIGS. 9 and 10), the lower semiconductor chip 120a and the upper semiconductor chip 120b may each include one semiconductor chip.

The plurality of connection films 130 may electrically connect the bonding pads 111 and 112 of the substrate 110 and the connection pads 120P of the plurality of semiconductor chips 120 to each other. The plurality of connection films 130 may be spaced apart from each other in a first direction (Y-direction) in which the connection pads 120P are arranged, and electrically connect the connection pads 120P and corresponding ones of the bonding pads 111 and 112 to each other in a second direction (X-direction), intersecting the first direction.

The plurality of connection films 130 may include a flexible film 131 and conductive lines 132 on the flexible film 131. The flexible film 131 may be a flexible film including polyimide. A material of the flexible film 131 is not limited thereto, and may be formed of or include a synthetic resin, for example, an epoxy resin, acrylic, polyether nitrile, polyether sulfone, polyethylene terephthalate, polyethylene naphthalate, or the like. The conductive lines 132 may include, for example, at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In) and zinc (Zn). The conductive lines 132 may include carbon (C).

Each of the plurality of connection films 130 may be electrically connected to at least two connection pads 120P in one semiconductor chip 120. For example, each of the plurality of connection films 130 may include a flexible film 131 covering at least two connection pads adjacent to each other in the first direction (Y-direction), among the connection pads 120P, and a plurality of conductive lines 132 extending in the second direction (X-direction) on the flexible film 131 and connected to the at least two connection pads 120P, respectively. The plurality of connection films 130 may include a flexible film 131 covering (three or more) connection pads 120P greater than those illustrated in the drawings, in number and conductive lines 132 corresponding to the connection pads 120P in number.

According to an example embodiment, a connection path between the plurality of semiconductor chips 120 may be formed using the flexible film 131 and the conductive lines 132 having a fine pitch, thereby further miniaturizing the connection pads 120p of the semiconductor chips 120. Horizontal and vertical sizes of the connection pads 120P (e.g., sizes or lengths of the connection pads 120p in the X-direction and the Y-direction) may be about 10 μm or less, for example, about 1 μm to about 10 μm, about 5 μm to about 10 μm, or the like. In addition, a distance d1 between the connection pads 120P may be about 25 μm or less, for example, about 5 μm to about 25 μm, about 10 μm to about 25 μm, about 15 μm to about 20 μm, or the like.

The plurality of connection films 130 may include a first connection film 130a and a second connection film 130b. The first connection film 130a and the second connection film 130b may include film structures combined in various forms to form an electrical connection path between the first connection pads P1 and the second connection pads P2, respectively. For example, the first connection film 130a may include a first sub-film 130al connecting the connection pads 120P of each of the lower semiconductor chips 120a to the first bonding pads 111, a second sub-film 130a2 connecting the connection pads 120P of each of the upper semiconductor chips 120b to each other, and a third sub-film 130a3 connecting the second sub-film 130a2 to the first bonding pads 111. For example, the second connection film 130b may be a single film connecting the connection pads 120P of each of the lower semiconductor chips 120a and the connection pads 120P of each of the upper semiconductor chips 120b to the second bonding pads 112. However, structures of the first connection film 130a and the second connection film 130b are not limited thereto.

The plurality of connection films 130 may be electrically connected to the substrate 110 and the semiconductor chips 120 through a plurality of connection members 135. The plurality of connection members 135 may be disposed between the plurality of conductive lines 132 and the connection pads 120P, and between the plurality of conductive lines 132 and the bonding pads 111 and 112. The plurality of connection members 135 may include a plurality of metal layers disposed on the connection pads 120P and the bonding pads 111 and 112, respectively. The plurality of connection members 135 may include at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In) and zinc (Zn). The plurality of connection members 135 may include carbon (C).

The mold 140 may cover the plurality of semiconductor chips 120 and the plurality of connection films 130, on the substrate 110. The mold 140 may include a thermosetting resin such as an epoxy resin, a thermoplastic resin such as polyimide or a resin such as a prepreg, an Ajinomoto build-up film (ABF), FR-4, bismaleimide triazine (BT), or an epoxy molding compound (EMC), in which the thermosetting resin or the thermoplastic resin is impregnated with an inorganic filler.

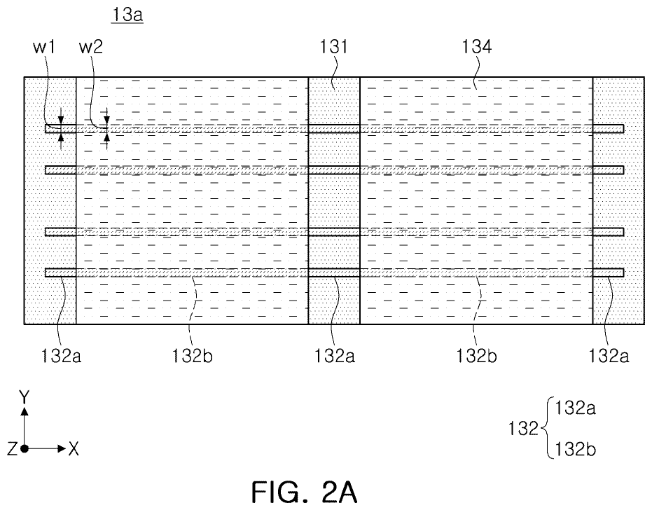

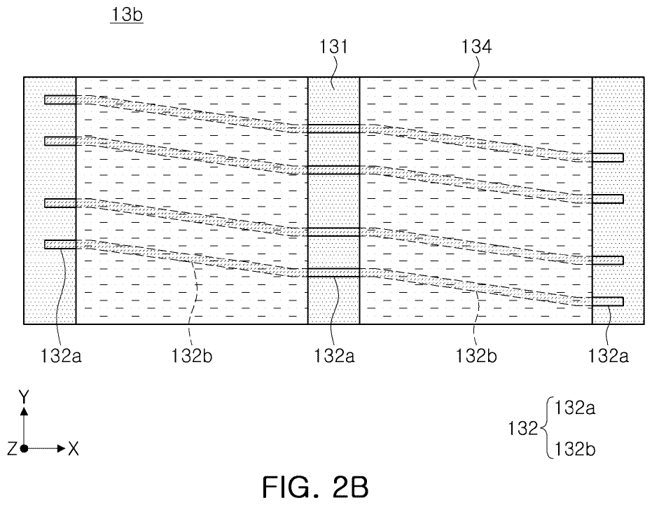

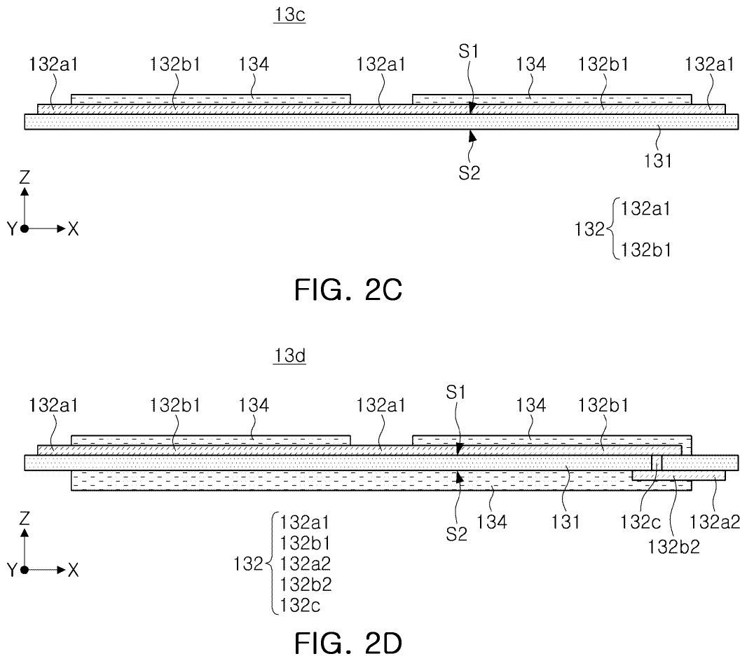

According to some example embodiments, the plurality of connection films 130, which are spaced apart from each other, may facilitate a flow of a molding material, thereby securing a filling property of the mold 140 in a space between the plurality of semiconductor chips 120 and the plurality of connection films 130, and suppressing the occurrence of voids. In addition, the plurality of connection films 130 may flatly extend on the connection pads 120P to reduce a mold gap, thereby reducing a thickness of the semiconductor package 100. A distance d2 between an uppermost semiconductor chip, among the plurality of semiconductor chips 120, and an uppermost surface of the mold 140 may be about 10 μm or less, about 1 μm to about 10 μm, about 3 μm to about 10 μm, about 5 μm to about 10 μm, about 8 μm to about 10 μm, or the like. Hereinafter, forms of the connection film 130 applied to some example embodiments will be described with reference to FIGS. 2A to 2D.

FIGS. 2A to 2D are diagrams of connection films 13a, 13b, 13c, and 13d according to some example modifications. FIGS. 2A to 2D illustrate the connection films 13a, 13b, 13c, and 13d, respectively.

Referring to FIG. 2A, the connection film 13a according to a modification may include conductive lines 132 formed on one surface and/or both surfaces of a flexible film 131. The conductive lines 132 may include terminal portions 132a connected to corresponding ones of connection pads 120P and bonding pads 111 and 112, respectively, and at least one pattern portion 132b between the terminal portions 132a. For example, each of the conductive lines 132 may include three terminal portions 132a and two pattern portions 132b. The connection film 13a may include conductive lines 132, greater or less in number than conductive lines (four), terminal portions 132a and pattern portions 132b illustrated in the drawings. The terminal portions 132a in the same conductive line 132 may be aligned in one direction (e.g., an X-direction), and the pattern portion 132b may extend in a straight line between the terminal portions 132a. A line width w1 of the terminal portion 132a may be the same or substantially equal to a line width w2 of the pattern portion 132b. Depending on example embodiments, the line width w1 of the terminal portion 132a may be greater than the line width w2 of the pattern portion 132b. The connection film 13a may further include a protective layer 134 covering at least a portion of each of the pattern portions 132b. The protective layer 134 may be formed of or include an insulating material, for example, a solder resist or a dry film resist. In some example embodiments, the protective layer 134 may be omitted.

Referring to FIG. 2B, a connection film 13b according to a modification may include a pattern portion 132b extending obliquely. The terminal portions 132a in the same conductive line 132 may be disposed to be misaligned with each other in one direction (e.g., an X-direction). The pattern portion 132b may extend obliquely between the terminal portions 132a. Depending on example embodiments, the pattern portion 132b may include two or more oblique extension portions having different inclination angles.

Referring to FIG. 2C, a connection film 13c according to a modification may include a conductive line 132 disposed on a first surface S1 of a flexible film 131. The conductive line 132 may include first terminal portions 132al and first pattern portions 132b1. A portion of the conductive line 132 may be covered by a protective layer 134. The protective layer 134 may have an opening region exposing at least a portion of each of the first terminal portions 132a1.

Referring to FIG. 2D, a connection film 13d according to a modification may include a conductive line 132 disposed on a first surface S1 and a second surface S2 of a flexible film 131. The conductive line 132 may include first terminal portions 132al and first pattern portions 132b1 on the first surface S1. The conductive line 132 may include a second terminal portion 132a2 and a second pattern portion 132b2 on the second surface S2. In addition, the conductive line 132 may further include a via portion 132c passing through the flexible film 131 to connect a first pattern portion 132b1 and a second pattern portion 132b2 to each other. The protective layer 134 may have an opening region exposing at least a portion of each of the first terminal portions 132al and the second terminal portion 132a2.

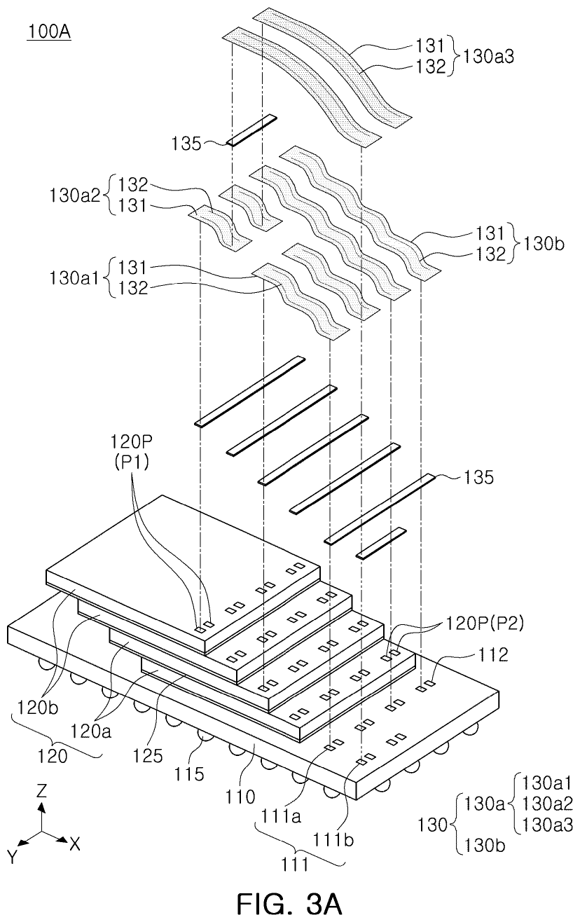

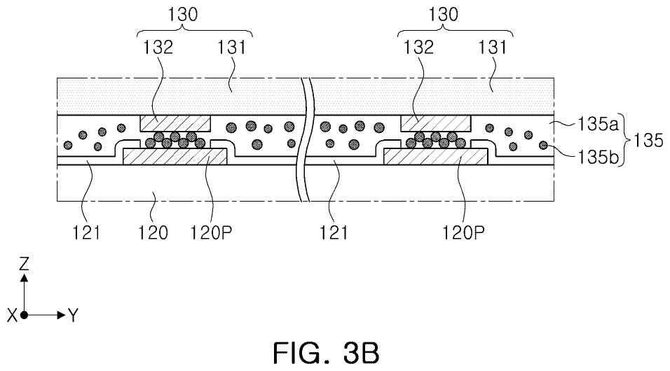

FIG. 3A is an exploded view of a semiconductor package 100A according to an example embodiment, and FIG. 3B is a partially enlarged view of a connection member 135 according to an example embodiment. FIG. 3B illustrates a connection member 135 interposed between connection pads 120P, that are adjacent to each other in a Y-direction in the same semiconductor chip 120, and a connection film 130.

Referring to FIGS. 3A and 3B, the semiconductor package 100A according to an example embodiment may have features the same as or similar to those described with reference to FIGS. 1A to 2D, except for including connection members 135 covering two or more pads in an arrangement direction of connection pads 120P or bonding pads 111 and 112 (e.g., in a first direction (Y-direction)). In an example embodiment, a plurality of connection members 135 may extend in the first direction (Y-direction), and may cover two or more connection pads 120P or two or more bonding pads 111 and 112, thereby further simplifying a process of manufacturing the semiconductor package 100A, and improving productivity.

The plurality of connection members 135 may be an anisotropic conductive film (ACF) including an insulating film portion 135a and conductive particles 135b dispersed in the insulating film portion 135a.

The insulating film portion 135a may include at least one of an epoxy resin, polyurethane, an acrylic resin, polyethylene, a silicone polymer, a styrene butadiene block copolymer, or a styrene-ethylene-propylene-styrene block copolymer.

The conductive particles 135b may have a form in which a conductive material is coated on a surface of a core particle. The core particle may be a plastic ball, but the present inventive concepts are not limited thereto. In some example embodiments, the core particle may be a carbon fiber or a conductive particle such as a metal ball. The conductive material coated on the surface of the core particle may include, for example, a metal material such as gold (Au), silver (Ag), nickel (Ni), lead (Pd), or the like. Depending on example embodiments, an insulating skin layer may be coated on a surface of the conductive material, that is, outermost portions of the conductive particles 135b. Accordingly, electrical conductivity may appear in a compression direction (Z-direction) by at least some conductive particles 135b in which the insulating skin layer is destroyed by high-temperature compression.

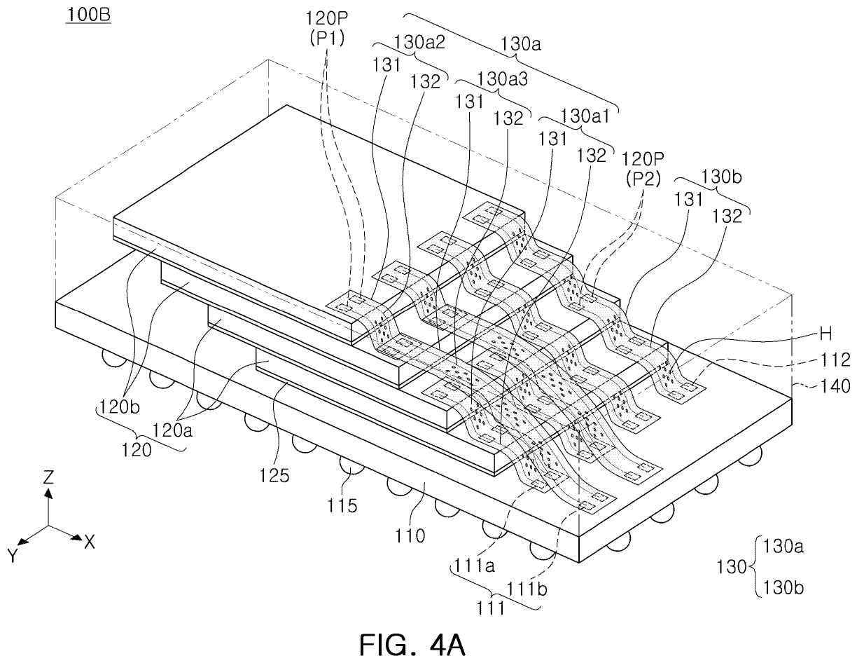

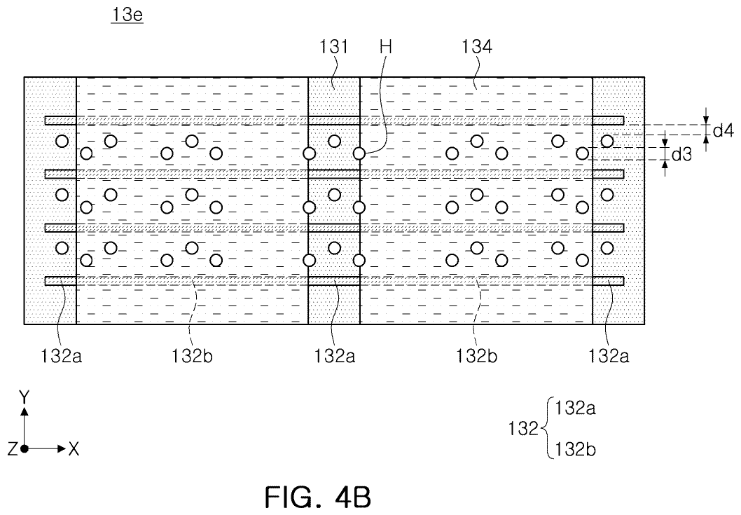

FIG. 4A is a perspective view of a semiconductor package 100B according to an example embodiment, and FIG. 4B is a plan view of a connection film 13e according to an example modification.

Referring to FIGS. 4A and 4B, the semiconductor package 100B according to an example embodiment may have features the same as or similar to those described with reference to FIGS. 1A to 3B, except that a plurality of connection films 130 include through-holes H passing through a flexible film 131. The plurality of connection films 130 may include a flexible film 131 extending on connection pads 120P and bonding pads 111 and 112, a plurality of conductive lines 132 on the flexible film 131, and through-holes H passing through the flexible film 131 between the plurality of conductive lines 132. The through-holes H may be spaced apart from the plurality of conductive lines 132 by a desired (or alternatively, predetermined) distance. The through-holes H facilitate a flow of a molding material, thereby securing a filling property of a mold 140 in a space between a plurality of semiconductor chips 120 and the plurality of connection films 130 and suppressing the occurrence of voids.

As illustrated in FIG. 4B, a connection film 13e according to a modification may include through-holes H passing through the flexible film 131 and/or a protective layer 134. The through-holes H may be formed between the conductive lines 132. The through-holes H may not be formed only in a specific region, but may be formed to be adjacent to both a terminal portion 132a and a pattern portion 132b. The through-holes H may be formed to have a size capable of securing flowability of the molding material. A diameter d3 of each of the through-holes H may be about 20 μm or more, for example, about 20 μm to about 60 μm, about 20 μm to about 50 μm, about 20 μm to about 40 μm, or the like. A minimum separation distance d4 between the through-holes H and the plurality of conductive lines 132 may be about 30 μm or more, for example, about 30 μm to about 60 μm, about 30 μm to about 50 μm, about 30 μm to about 40 μm, or the like. However, the present inventive concepts are not limited thereto, and the diameter d3 of each of the through-holes H and the separation distance d4 may be determined by a type of molding material, a pitch between the conductive lines 132, or the like.

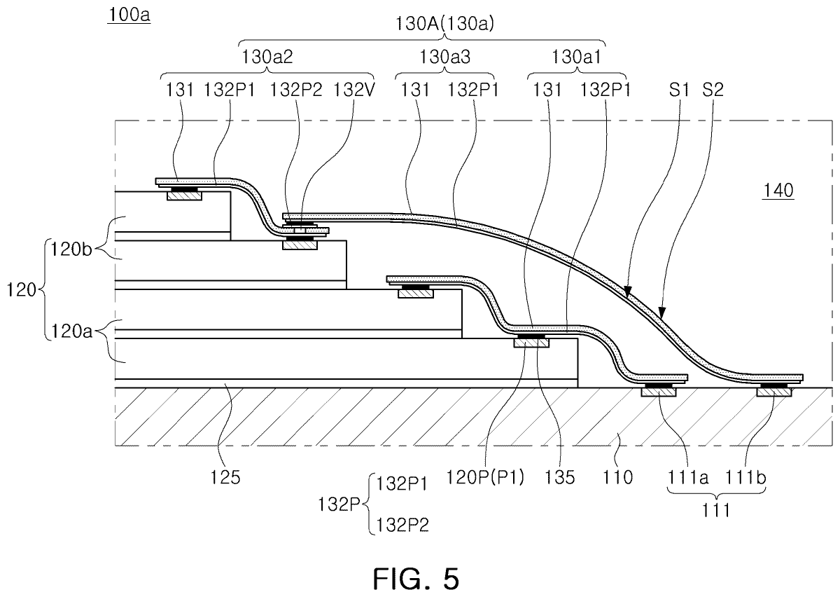

FIGS. 5 to 10 are diagrams of forms of a connection film applied to a semiconductor package according to an example modification.

Referring to FIG. 5, in a semiconductor package 100a according to an example modification, a connection film 130A according to a first example embodiment may electrically connect connection pads 120P and bonding pads 111 to each other, and may include a flexible film 131 having a first surface S1 facing a substrate 110, and a second surface S2 opposite to the first surface S1, and a conductive pattern 132P extending along at least one surface, among the first surface S1 and the second surface S2. The connection film 130A according to the first example may form a signal connection path connecting first connection pads P1 and first bonding pads 111 to each other. The connection film 130A according to the first example may include a first sub-film 130al, a second sub-film 130a2, and a third sub-film 130a3. A mold 140 may be filled between a plurality of semiconductor chips 120, and the first sub-film 130al, the second sub-film 130a2, and the third sub-film 130a3.

The first sub-film 130al may electrically connect the connection pads 120P of the at least one lower semiconductor chip 120a to the bonding pads 111a of the first group. The first sub-film 130al may include a flexible film 131 and a conductive pattern 132P. The conductive pattern 132P is disposed on the first surface S1 of the flexible film 131 and may include a front pattern layer 132P1 connecting the connection pads 120P to the bonding pads 111a of the first group.

The second sub-film 130a2 may electrically connect the connection pads 120P of each of the upper semiconductor chips 120b to each other so that at least one upper semiconductor chip 120b is connected to the bonding pads 111b of the second group via the third sub-film 130a3 to be formed thereon. The second sub-film 130a2 may include a flexible film 131 and a conductive pattern 132P. The conductive pattern 132P may include a front pattern layer 132P1 disposed on the first surface S1 of the flexible film 131 and connected to the connection pads 120P, a rear pattern layer 132P2 disposed on the second surface S2 of the flexible film 131, and a conductive via 132V passing through the flexible film 131 and connecting the front pattern layer 132P1 and the rear pattern layer 132P2.

The third sub-film 130a3 may connect the second sub-film 130a2 and a second group of bonding pads 111b, to each other. The third sub-film 130a3 may include the flexible film 131 and the conductive pattern 132P. The conductive pattern 132P may include a front pattern layer 132P1 disposed on the first surface S1 of the flexible film 131, and may include the front pattern layer 132P1 connecting a rear pattern layer 132P2 of the second sub-film 130a2 and the second group of bonding pads 111b to each other.

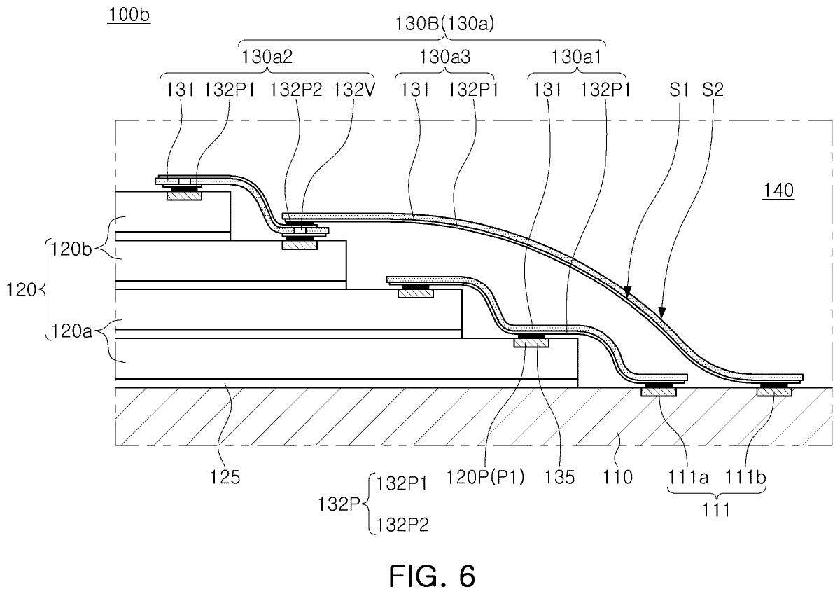

Referring to FIG. 6, in a semiconductor package 100b according to an example modification, a connection film 130B according to a second example embodiment may form a signal connection path connecting first connection pads P1 and first bonding pads 111 to each other. The connection film 130B according to the second example embodiment may include a first sub-film 130a1, a second sub-film 130a2, and a third sub-film 130a3. A mold 140 may be filled between a plurality of semiconductor chips 120, and the first sub-film 130al, the second sub-film 130a2, and the third sub-film 130a3.

The connection film 130B according to the second example embodiment may have features substantially the same as those of the connection film 130A of FIG. 5, except for a conductive pattern 132P of the second sub-film 130a2, and thus repeated descriptions will be omitted. The conductive pattern 132P of the second sub-film 130a2 may include front pattern layers 132P1 spaced apart from each other on a first surface S1 of a flexible film 131 and connected to connection pads 120P, respectively, a rear pattern layer 132P2 extending onto a second surface S2 of the flexible film 131, and a conductive via 132V passing through the flexible film 131 and connecting the front pattern layer 132P1 and the rear pattern layer 132P2 to each other.

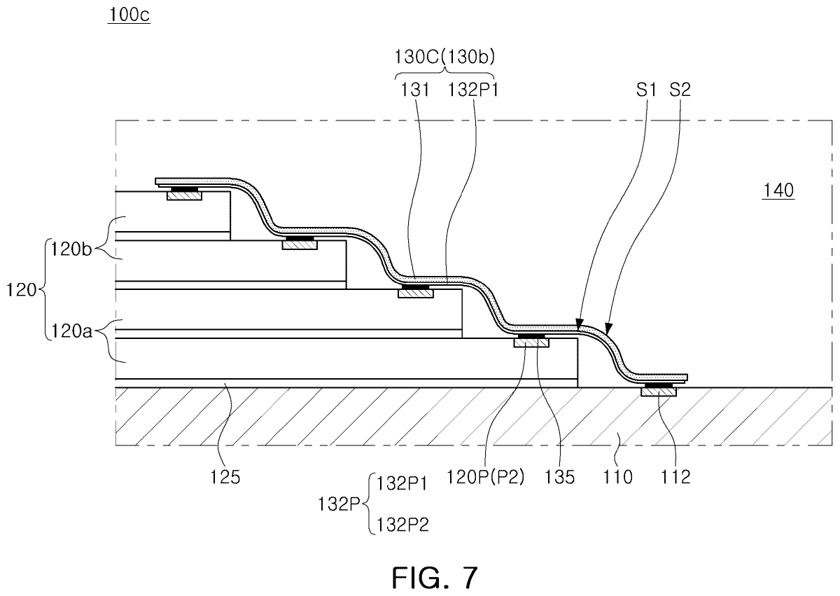

Referring to FIG. 7, in a semiconductor package 100c according to an example modification, a connection film 130C according to a third example embodiment may form a power and ground connection path connecting second connection pads P2 and second bonding pads 112 to each other. The connection film 130C according to the third example embodiment may include a single film. A mold 140 may be filled between a plurality of semiconductor chips 120 and the connection film 130C according to the third example embodiment. The connection film 130C according to the third example embodiment may include a front pattern layer 132P1 that extends along a first surface S1 of a flexible film 131, and connects connection pads 120P and the bonding pad 112 to each other.

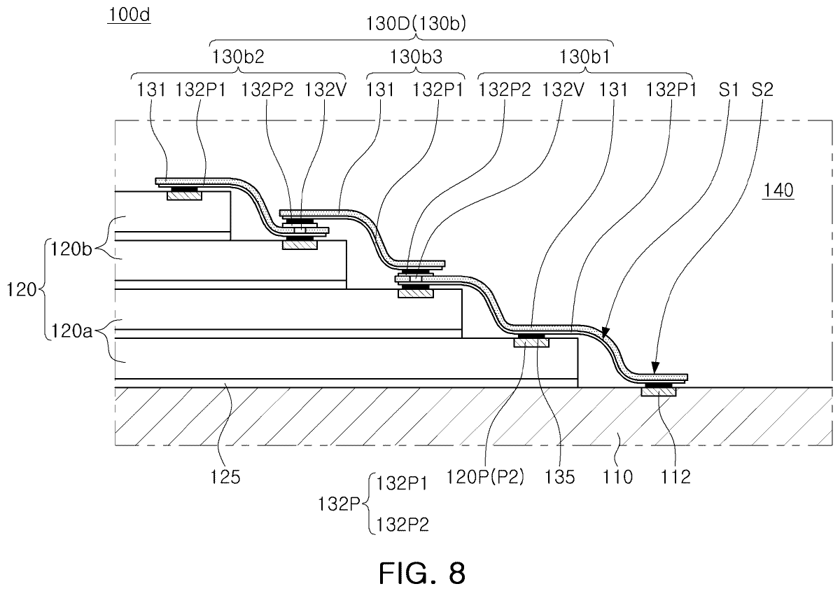

Referring to FIG. 8, in a semiconductor package 100d according to an example modification, a connection film 130D according to a fourth example embodiment may form a power and ground connection path connecting second connection pads P2 and second bonding pads 112 to each other. The connection film 130D according to the fourth example embodiment may include a fourth sub-film 130b1, a fifth sub-film 130b2, and a sixth sub-film 130b3. A mold 140 may be filled between a plurality of semiconductor chips 120, and the fourth sub-film 130b1, the fifth sub-film 130b2, and the sixth sub-film 130b3.

The fourth sub-film 130b1 may electrically connect connection pads 120P of at least one lower semiconductor chip 120a and the second bonding pads 112 to each other. The fourth sub-film 130b1 may include a flexible film 131 and a conductive pattern 132P. The conductive pattern 132P may include a front pattern layer 132P1 disposed on a first surface S1 of the flexible film 131, the front pattern layer 132P1 connecting the connection pads 120P and the second bonding pads 112 to each other, a rear pattern layer 132P2 on a second surface S2 of the flexible film 131, and a conductive via 132V passing through the flexible film 131 and connecting the front pattern layer 132P1 and the rear pattern layer 132P2 to each other.

The fifth sub-film 130b2 may electrically connect connection pads 120P of each of the upper semiconductor chips 120b to each other so that at least one upper semiconductor chip 120b is connected to the second bonding pads 112 via the sixth sub-film 130b3 to be formed thereon. A conductive pattern 132P of the fifth sub-film 130b2 may include a front pattern layer 132P1 disposed on the first surface S1 of the flexible film 131 and connected to the connection pads 120P, a rear pattern layer 132P2 disposed on the second surface S2 of the flexible film, and a conductive via 132V passing through the flexible film 131 and connecting the front pattern layer 132P1 and the rear pattern layer 132P2 to each other.

The sixth sub-film 130b3 may connect the fifth sub-film 130b2 and the fourth sub-film 130b1 to each other. A conductive pattern 132P of the sixth sub-film 130b3 may include a front pattern layer 132P1 disposed on the first surface S1 of the flexible film 131 and connecting the rear pattern layer 132P2 of the fifth sub-film 130b2 and the rear pattern layer 132P2 of the fourth sub-film 130b1 to each other.

Referring to FIG. 9, in a semiconductor package 100e according to an example modification, a connection film 130E according to a fifth example embodiment may form a signal connection path connecting first connection pads P1 and first bonding pads 111 to each other. The semiconductor package 100e according to an example modification may include at least one lower semiconductor chip 120a and at least one upper semiconductor chip 120b. The at least one lower semiconductor chip 120a and the at least one upper semiconductor chip 120b may overlap each other and may be aligned with each other in a vertical direction. Connection pads 120P of the lower semiconductor chip 120a may overlap the upper semiconductor chip 120b, which adjacent to the lower semiconductor chip 120a in the vertical direction.

The connection film 130E according to the fifth example embodiment may include a first sub-film 130a1 and a second sub-film 130a2, corresponding to the at least one lower semiconductor chip 120a and the at least one upper semiconductor chip 120b, respectively. A mold 140 may be filled between a substrate 110, the first sub-film 130al, and the second sub-film 130a2.

The first sub-film 130al may electrically connect connection pads 120P of the at least one lower semiconductor chip 120a and a first group of bonding pads 111a to each other. A conductive pattern 132P of the first sub-film 130al may include a front pattern layer 132P1 connecting the connection pads 120P and the first group of bonding pads 111a to each other on a first surface S1 of a flexible film 131. The first sub-film 130al may flatly extend on the connection pads 120P of the lower semiconductor chip 120a to reduce or minimize a distance between the lower semiconductor chip 120a and the upper semiconductor chip 120b. For example, a thickness T of an adhesive layer 125′ between the lower semiconductor chip 120a and the upper semiconductor chip 120b may be about 10 μm or less, for example, about 1 μm to about 10 μm, about 5 μm to about 10 μm, or the like. A portion of the first sub-film 130a1 may be buried in the adhesive layer 125′.

The second sub-film 130a2 may electrically connect connection pads 120P of the at least one upper semiconductor chip 120b and a second group of bonding pads 111b to each other. A conductive pattern 132P of the second sub-film 130a2 may include a front pattern layer 132P1 connecting the connection pads 120P and the second group of bonding pads 111b to each other on the first surface S1 of the flexible film 131.

Referring to FIG. 10, in a semiconductor package 100f according to an example modification, a connection film 130F according to a sixth example embodiment may form a power and ground connection path connecting second connection pads P2 and second bonding pads 112 to each other. The connection film 130F according to the sixth example embodiment may include a fourth sub-film 130b1 and a fifth sub-film 130b2. A mold 140 may be filled between a plurality of semiconductor chips 120, the fourth sub-film 130b1, and the fifth sub-film 130b2.

The fourth sub-film 130b1 may electrically connect connection pads 120P of at least one lower semiconductor chip 120a and the second bonding pads 112 to each other. A conductive pattern 132P of the fourth sub-film 130b1 may include a front pattern layer 132P1 disposed on a first surface S1 of a flexible film 131 and connecting the connection pads 120P and the second bonding pads 112 to each other, a rear pattern layer 132P2 on a second surface S2 of the flexible film 131, and a conductive via 132V passing through the flexible film 131 and connecting the front pattern layer 132P1 and the rear pattern layer 132P2 to each other.

The fifth sub-film 130b2 may electrically connect connection pads 120P of at least one upper semiconductor chip 120b and the second bonding pads 112 to each other. The conductive pattern 132P of the fifth sub-film 130b2 may include a front pattern layer 132P1 disposed on the first surface S1 of the flexible film 131 and connecting the connection pads 120P of at least one upper semiconductor chip 102b and the rear pattern layer 132P2 of the fourth sub-film 130b1 to each other. The rear pattern layer 132P2 of the fourth sub-film 130b1 and the front pattern layer 132P1 of the fifth sub-film 130b2 may be connected to each other by a connection member 135. As described, connection films according to some example embodiments may form a connection structure in which various types of films are combined with each other.

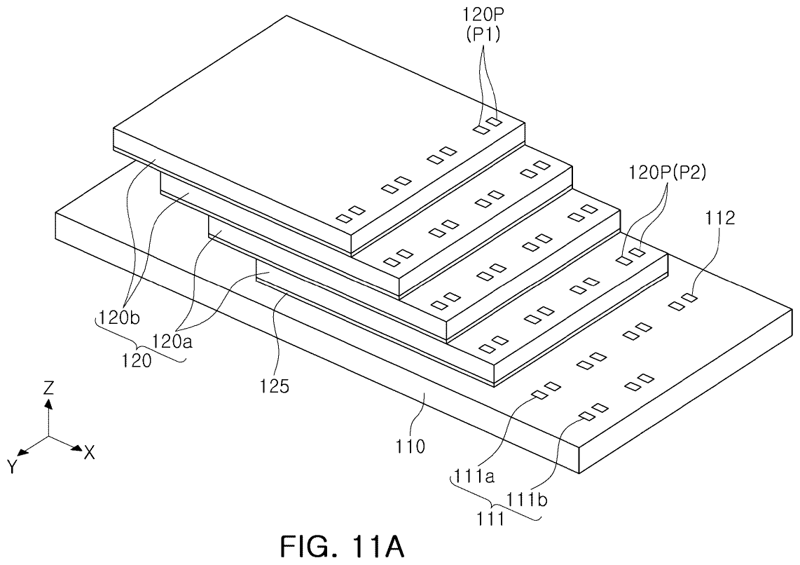

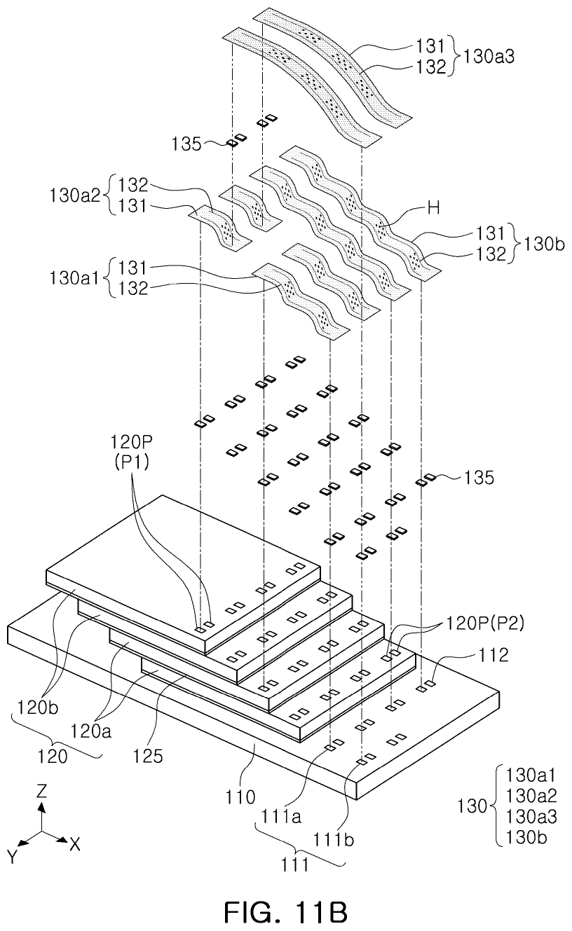

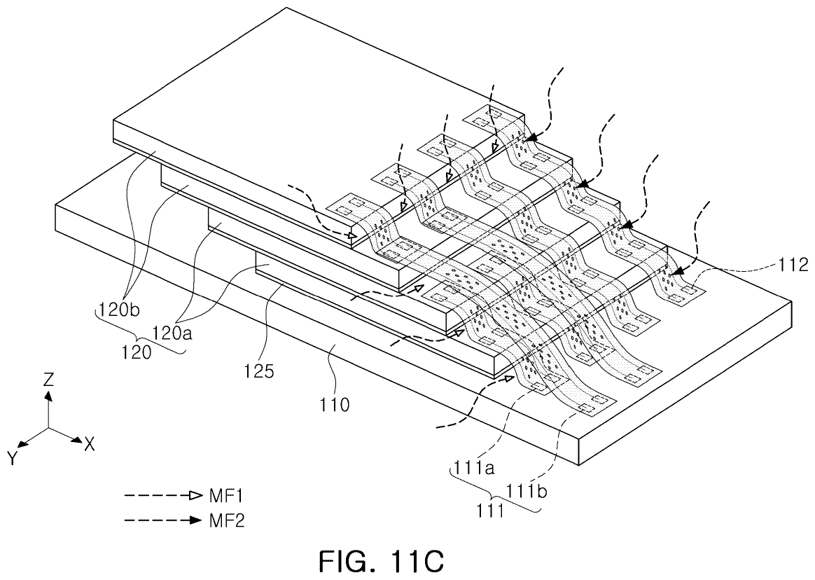

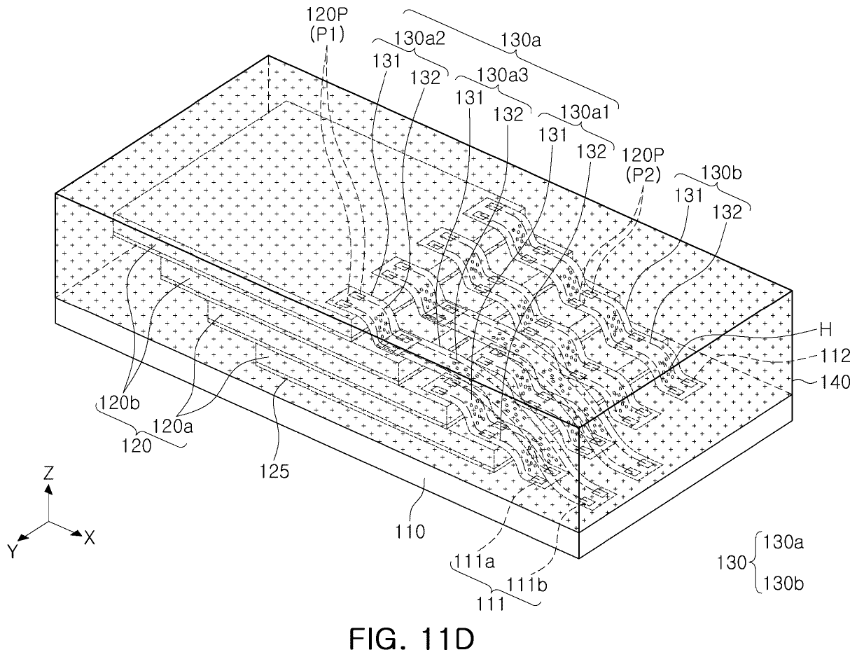

FIGS. 11A to 11D are diagrams of a process of manufacturing a semiconductor package according to an example embodiment.

Referring to FIG. 11A, a plurality of semiconductor chips 120 may be stacked on a substrate 110. The substrate 110 may be a strip substrate including a plurality of unit substrates. The plurality of semiconductor chips 120 may be stacked on the unit substrates. The plurality of semiconductor chips 120 may be attached to each other by adhesive films 125. The plurality of semiconductor chips 120 may be disposed such that connection pads 120P are adjacent to the bonding pads 111 and 112 of the substrate 110, respectively. The plurality of semiconductor chips 120 may be shifted in one direction (e.g., an X direction) to expose the connection pads 120P in a vertical direction (Z direction).

Referring to FIG. 11B, a plurality of connection members 135 and a plurality of connection films 130 may be disposed. The plurality of connection members 135 may form a metal layer on the connection pads 120P and the bonding pads 111 and 112 using a plating process, a dispensing process, or the like (see FIG. 1B), or may be formed by attaching an anisotropic conductive film (e.g., a film embedded with conductive particles that allow electrical connections to be made in one direction (vertically) while maintaining insulation in the perpendicular direction (horizontally)) on the connection pads 120P and the bonding pads 111 and 112 (see FIG. 3B). The plurality of connection films 130 may be flatly attached to upper surfaces of the semiconductor chips 120, and may be gently bent on side surfaces of the semiconductor chips 120. A plurality of connection films 130 may be spaced apart from each other to ensure flowability of a molding material in a subsequent process. In an example embodiment, the plurality of connection films 130 may further include through-holes H between the conductive lines 132.

Referring to FIG. 11C, the molding material may flow on the substrate 110. The molding material may cover the plurality of semiconductor chips 120 and the plurality of connection films 130 using a transfer process or a compression process. The molding material may flow through a first path MF1 between the plurality of connection films 130, and a second path MF2 passing through the through-holes H. According to an example embodiment, a flow of the molding material may be facilitated by the first path MF1 and the second path MF2.

Referring to FIG. 11D, a mold 140, encapsulating the plurality of semiconductor chips 120 and the plurality of connection films 130, may be formed. The mold 140 may be formed by curing the molding material (e.g., an EMC) covering the plurality of semiconductor chips 120 and the plurality of connection films 130. A planarization process may be applied to an upper portion of the mold 140. According to an example embodiment, the mold 140 may be ground to have a further reduced thickness, thereby implementing a semiconductor package having a reduced thickness. Thereafter, a connection bump may be formed, and a sawing process may be performed to separate individual packages from each other.

According to some example embodiments of the present inventive concepts, a plurality of connection films connecting a plurality of stacked semiconductor chips to a substrate may be introduced, thereby providing a semiconductor package having improved productivity and/or reliability.

While some example embodiments have been shown and described above, it will be apparent to those skilled in the art that modifications and variations could be made without departing from the scope of the present inventive concepts as defined by the appended claims.

What is claimed is:

1. A semiconductor package comprising:
a substrate including bonding pads;
a plurality of semiconductor chips stacked on the substrate, the plurality of semiconductor chips each including a lower surface facing the substrate, an upper surface opposite to the lower surface, and connection pads being on the upper surface;
a plurality of connection films spaced apart from each other in a first direction, the plurality of connection films electrically connecting the connection pads and corresponding ones of the bonding pads to each other in a second direction intersecting the first direction;
a mold covering the plurality of semiconductor chips and the plurality of connection films; and
connection bumps being under the substrate, the connection bumps electrically connected to the bonding pads,
wherein each of the plurality of connection films includes a flexible film covering at least two connection pads adjacent to each other in the first direction, among the connection pads, and a plurality of conductive lines extending in the second direction on the flexible film, the plurality of conductive lines respectively connected to the at least two connection pads.

2. The semiconductor package of claim 1, wherein
the bonding pads of the substrate include first bonding pads and second bonding pads, the first bonding pads and second bonding pads being spaced apart from each other, and
the plurality of connection films include a first connection film and a second connection film, the first connection film connected to the first bonding pad, the second connection film connected to the second bonding pad.

3. The semiconductor package of claim 2, wherein
the plurality of semiconductor chips include at least two lower semiconductor chips and at least two upper semiconductor chips, the at least two upper semiconductor chips being on the lower semiconductor chips, and
the first connection film includes a first sub-film, a second sub-film, and a third sub-film, the first sub-film connecting the connection pads of each of the lower semiconductor chips to the first bonding pads, the second sub-film connecting the connection pads of the upper semiconductor chips to each other, the third sub-film connecting the second sub-film to the first bonding pads.

4. The semiconductor package of claim 3, wherein
the first bonding pads include a first group of bonding pads and a second group of bonding pads, the first group of bonding pads connected to the first sub-film, the second group of bonding pads connected to the third sub-film, and
the first group of bonding pads and the second group of bonding pads are electrically insulated from each other.

5. The semiconductor package of claim 2, wherein
the plurality of semiconductor chips includes at least two lower semiconductor chips and at least two upper semiconductor chips, the at least two upper semiconductor chips being on the lower semiconductor chips, and
the second connection film is a single film connecting the connection pads of each of the lower semiconductor chips and the connection pads of each of the upper semiconductor chips to the second bonding pads.

6. The semiconductor package of claim 1, further comprising:
a plurality of connection members being between the plurality of conductive lines and the connection pads and between the plurality of conductive lines and the bonding pads.

7. The semiconductor package of claim 6, wherein the plurality of connection members include an insulating film portion and conductive particles dispersed in the insulating film portion, the insulating film portion extending in the first direction and covering at least two of the connection pads or at least two of the bonding pads.

8. The semiconductor package of claim 6, wherein the plurality of connection members include a plurality of metal layers disposed on the connection pads and the bonding pads, respectively.

9. The semiconductor package of claim 1, wherein the plurality of connection films include through-holes passing through the flexible film and spaced apart from the plurality of conductive lines.

10. The semiconductor package of claim 9, wherein a diameter of each of the through-holes is 20 μm or more.

11. The semiconductor package of claim 9, wherein a separation distance between the through-holes and the plurality of conductive lines is 30 μm or more.

12. The semiconductor package of claim 1, wherein
the plurality of conductive lines include terminal portions and at least one pattern portion, the terminal portions connected to corresponding ones of the connection pads and the bonding pads, respectively, the at least one pattern portion being between the terminal portions, and
the plurality of connection films further include a protective layer covering at least a portion of the at least one pattern portion.

13. The semiconductor package of claim 1, wherein the mold fills a space between the plurality of semiconductor chips and the plurality of connection films.

14. The semiconductor package of claim 1, wherein a distance between an uppermost semiconductor chip, among the plurality of semiconductor chips, and an uppermost surface of the mold is 10 μm or less.

15. The semiconductor package of claim 1, wherein a distance between the connection pads of each of the plurality of semiconductor chips is 25 μm or less.

16. A semiconductor package comprising:
a substrate including bonding pads;
a plurality of semiconductor chips including at least one lower semiconductor chip and at least one upper semiconductor chip, the at least one lower semiconductor chip and the at least one upper semiconductor chip stacked being in order on the substrate, the at least one lower semiconductor chip and the at least one upper semiconductor chip each including connection pads;
a plurality of connection films electrically connecting the connection pads and the bonding pads to each other, the plurality of connection films each including a flexible film and a conductive pattern, the flexible film having a first surface facing the substrate and a second surface opposite to the first surface, the conductive pattern extending along at least one surface, among the first and second surfaces; and
a mold between the plurality of semiconductor chips and the plurality of connection films,
wherein the plurality of connection films include a first sub-film and a second sub-film, the first sub-film electrically connecting the connection pads of the at least one lower semiconductor chip and the bonding pads to each other, the second sub-film electrically connecting the connection pads of the at least one upper semiconductor chip and the bonding pads to each other.

17. The semiconductor package of claim 16, wherein
the bonding pads include a first group of bonding pads and a second group of bonding pads, the first group of bonding pads connected to the first sub-film, the second group of bonding pads connected to the second sub-film,
the plurality of connection films further include a third sub-film connecting the second sub-film and the second group of bonding pads to each other,
the first sub-film includes a first flexible film and a first conductive pattern,
the first conductive pattern includes a front pattern layer, the front pattern layer being on the first surface of the first flexible film and connecting the connection pads and the first group of bonding pads to each other,
the second sub-film includes a second flexible film and a second conductive pattern,
the second conductive pattern includes a front pattern layer, a rear pattern layer, and a conductive via, the front patter layer being on the first surface of the second flexible film and connected to the connection pads, the rear pattern layer being on the second surface of the second flexible film, the conductive via passing through the second flexible film and connecting the front pattern layer and the rear pattern layer to each other,
the third sub-film includes a third flexible film and a third conductive pattern, and
the third conductive pattern includes a front pattern layer being on the first surface of the third flexible film, the front pattern layer of the third conductive pattern connecting the rear pattern layer of the second conductive pattern and the second group of connection pads to each other.

18. The semiconductor package of claim 16, wherein
the connection pads of the at least one lower semiconductor chip overlap the at least one upper semiconductor chip, adjacent in a vertical direction,
the first sub-film includes a first flexible film and a first conductive pattern,
the first conductive pattern includes a front pattern layer, a rear pattern layer, and a conductive via, the front pattern layer being on the first surface of the first flexible film and connecting the connection pads of the at least one lower semiconductor chip and the bonding pads to each other, the rear pattern layer being on the second surface of the first flexible film, the conductive via passing through the first flexible film and connecting the front pattern layer and the rear pattern layer to each other,
the second sub-film includes a second flexible film and a second conductive pattern,
the second conductive pattern includes a front pattern layer and a rear pattern layer, the front pattern layer being on the first surface of the second flexible film and connecting the rear pattern layer of the first conductive pattern and the connection pads to each other.

19. The semiconductor package of claim 18, further comprising:
an adhesive layer being between the at least one lower semiconductor chip and the at least one upper semiconductor chip, the at least one lower semiconductor chip and the at least one upper semiconductor chip being adjacent to each other in the vertical direction, the adhesive layer covering at least a portion of the first sub-film,
wherein a thickness of the adhesive layer above is 10 μm or less.

20. A semiconductor package comprising:
a substrate including bonding pads;
a plurality of semiconductor chips stacked on the substrate, the plurality of semiconductor chips each including a lower surface facing the substrate, an upper surface opposite to the lower surface, and connection pads on the upper surface;
a plurality of connection films electrically connecting the connection pads and the bonding pads to each other;
a mold encapsulating the plurality of semiconductor chips and the plurality of connection films, the mold filling a space between the plurality of semiconductor chips and the plurality of connection films; and
connection bumps being under the substrate, the connection bumps electrically connected to the bonding pads,
wherein the plurality of connection films include
a flexible film extending on the connection pads and the bonding pads,
a plurality of conductive lines on the flexible film, the plurality of conductive lines electrically connecting the connection pads and the bonding pads corresponding to each other, and
through-holes being between the plurality of conductive lines and passing through the flexible film.
